(19) United States
(12) Patent Application Publication
(10) Pub. No.: US 2025/0344428 A1
(43) Pub. Date: Nov. 6, 2025

(54) SELECTIVE BOTTOM SEED LAYER FORMATION FOR BOTTOM-UP EPITAXY

(71) Applicant: Taiwan Semiconductor Manufacturing Co., Ltd., Hsinchu (TW)

(72) Inventors: Yu-Cheng Shiau, Hsinchu (TW); Chung-Ting Ko, Kaohsiung City (TW); Ting-Hsiang Chang, New Taipei City (TW); Shu Ling Liao, Taichung City (TW); Sung-En Lin, Xionglin Township (TW); Tai-Chun Huang, Hsinchu (TW); Tze-Liang Lee, Hsinchu (TW)

(21) Appl. No.: 19/267,907

(22) Filed: Jul. 14, 2025

Related U.S. Application Data
(63) Continuation of application No. 18/476,619, filed on Sep. 28, 2023.
(60) Provisional application No. 63/509,802, filed on Jun. 23, 2023.

(51) Int. Cl. H10D 30/43; H01L 21/02; H01L 21/306; H10D 30/67; H10D 62/10; H10D 64/23; H10D 84/83

(52) U.S. Cl. CPC H10D 30/43; H01L 21/0262; H01L 21/30604; H10D 30/6735; H10D 30/6757; H10D 62/121; H10D 64/258; H10D 84/83

(57) ABSTRACT

A method includes etching a semiconductor region aside of a gate stack to form a recess, forming a dielectric layer at a bottom of the recess, selectively forming a first semiconductor layer at the bottom of the recess, and epitaxially growing a second semiconductor layer on the first semiconductor layer. A bottom surface of the first semiconductor layer forms an interface with a top surface of the dielectric layer, with the interface extending to opposing sides of the recess. The selectively forming the first semiconductor layer comprises a first deposition process performed under first process conditions. The second semiconductor layer is formed using a second deposition process under second process conditions. The second process conditions are different from the first process conditions.

### PRIORITY CLAIM AND CROSS-REFERENCE

This application is a continuation of U.S. patent application Ser. No. 18/476,619, filed on Sep. 28, 2023, which application claims the benefit of the following provisionally filed U.S. Patent Application No. 63/509,802, filed on Jun. 23, 2023, and entitled “Topographic Selective Bottom Seed Layer for Epitaxy Bottom-Up Growth,” which applications are hereby incorporated herein by reference.

### BACKGROUND

Semiconductor devices are used in a variety of electronic applications, such as personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (for example, transistors, diodes, resistors, capacitors, etc.) through continual reduction in minimum feature size, which allows more components to be integrated into a given area. As the minimum feature sizes are reduced, however, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-4, 5A, 5B, 6A, 6B, 7A, 7B, 8A, 8B, 9A, 9B, 10A, 10B, 11A, 11B, 12A, 12B, 13A, 13B, 14A, and 14B illustrate the cross-sectional views of intermediate stages in the formation of a Gate All-Around (GAA) transistor in accordance with some embodiments.

FIGS. 15, 16, 17A, 17B, 18A, 18B, 19A, 19B and 20 through 26 illustrate the cross-sectional views of intermediate stages in the formation of dielectric layers and overlying source/drain regions in accordance with some embodiments.

FIG. 27 illustrates a process flow for forming a GAA transistor in accordance with some embodiments.

FIG. 28 illustrates a process flow for forming dielectric layers and overlying source/drain regions in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A Gate All-Around (GAA) transistor having dielectric layers and source/drain regions deposited into source/drain recesses is provided. The methods of forming the dielectric layers and the source/drain regions are also provided. In accordance with some embodiments, after the formation of a source/drain recess, a dielectric layer is formed at the bottom of the source/drain recess. A plurality of cycles (each including a deposition process and an etch-back process) are then performed to selectively deposit a first semiconductor layer at the bottom of the recess and on the dielectric layer. The first semiconductor layer is amorphous. An epitaxy process is then preformed to grow a second semiconductor layer on the first semiconductor layer. The second semiconductor layer may include an amorphous portion on the first semiconductor layer, and a crystalline portion over the amorphous portion. The source/drain region is thus grown bottom-up, and the likely void in the source/drain region is reduced or eliminated.

Although GAA transistors are used as an example to discuss the concept of the present disclosure, the embodiments may be applied on other types of transistors including and not limited to Fin Field-Effect Transistors (FinFETs), planar transistors, and the like. Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

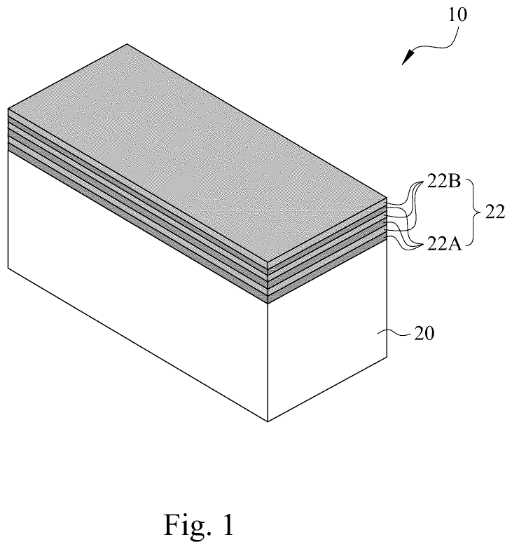

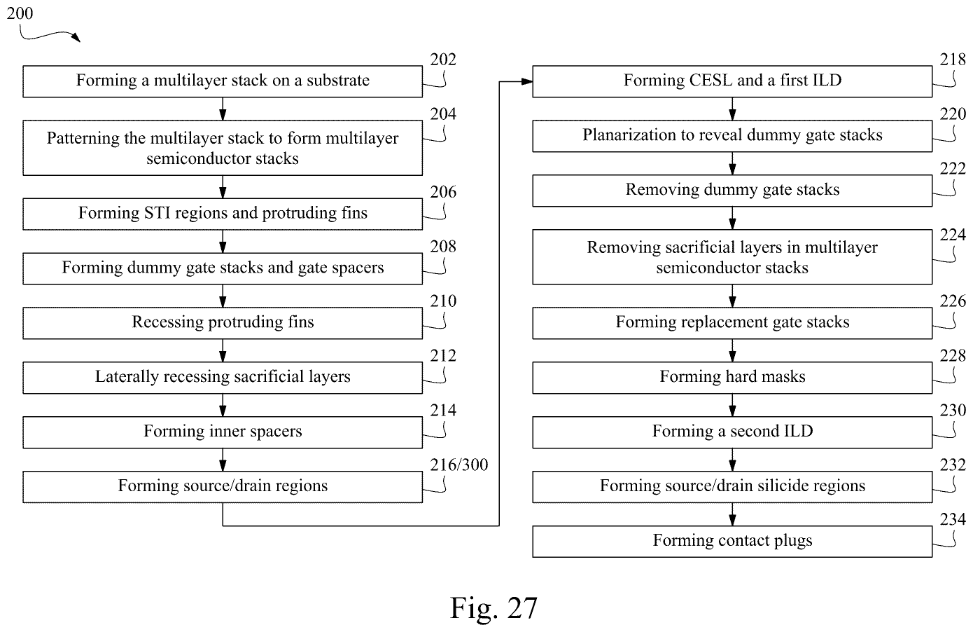

FIGS. 1-4, 5A, 5B, 6A, 6B, 7A, 7B, 8A, 8B, 9A, 9B, 10A, 10B, 11A, 11B, 12A, 12B, 13A, 13B, 14A, and 14B illustrate the cross-sectional views of intermediate stages in the formation of a GAA transistor in accordance with some embodiments of the present disclosure. The corresponding processes are also reflected schematically in the process flow shown in FIG. 27.

Referring to FIG. 1, a perspective view of wafer 10 is shown. Wafer 10 includes a multilayer structure comprising multilayer stack 22 on substrate 20. In accordance with some embodiments, substrate 20 is a semiconductor substrate, which may be a silicon substrate, a silicon germanium (SiGe) substrate, or the like, while other substrates and/or structures, such as semiconductor-on-insulator (SOI), strained SOI, silicon germanium on insulator, or the like, could be used. Substrate 20 may be doped as a p-type semiconductor, although in other embodiments, it may be doped as an n-type semiconductor.

In accordance with some embodiments, multilayer stack 22 is formed through a series of deposition processes for depositing alternating materials. The respective process is illustrated as process 202 in the process flow 200 shown in FIG. 27. In accordance with some embodiments, multilayer stack 22 comprises first layers 22A formed of a first semiconductor material and second layers 22B formed of a second semiconductor material different from the first semiconductor material.

In accordance with some embodiments, the first semiconductor material of a first layer 22A is formed of or comprises SiGe, Ge, Si, GaAs, InSb, GaSb, InAlAs, InGaAs, GaSbP, GaAsSb, or the like. In accordance with some embodiments, the deposition of first layers 22A (for example, SiGe) is through epitaxial growth, and the corresponding deposition method may be Vapor-Phase Epitaxy (VPE), Molecular Beam Epitaxy (MBE), Chemical Vapor deposition (CVD), Low Pressure CVD (LPCVD), Atomic Layer Deposition (ALD), Ultra High Vacuum CVD (UHVCVD), Reduced Pressure CVD (RPCVD), or the like. In accordance with some embodiments, the first layer 22A is formed to a first thickness in the range between about 30 Å and about 300 Å. However, any suitable thickness may be utilized while remaining within the scope of the embodiments.

Once the first layer 22A has been deposited over substrate 20, a second layer 22B is deposited over the first layer 22A. In accordance with some embodiments, the second layers 22B is formed of or comprises a second semiconductor material such as Si, SiGe, Ge, GaAs, InSb, GaSb, InAlAs, InGaAs, GaSbP, GaAsSb, combinations of these, or the like, with the second semiconductor material being different from the first semiconductor material of first layer 22A. For example, in accordance with some embodiments in which the first layer 22A is silicon germanium, the second layer 22B may be formed of silicon, or vice versa. It is appreciated that any suitable combination of materials may be utilized for first layers 22A and the second layers 22B.

In accordance with some embodiments, the second layer 22B is epitaxially grown on the first layer 22A using a deposition technique similar to that is used to form the first layer 22A. In accordance with some embodiments, the second layer 22B is formed to a similar thickness to that of the first layer 22A. The second layer 22B may also be formed to a thickness that is different from the first layer 22A. In accordance with some embodiments, the first layer 22A has thickness in the range between about 4 nm and 7 nm, while the second layer 22B has thickness in the range between about 8 nm and 12 nm, for example.

Once the second layer 22B has been formed over the first layer 22A, the deposition process is repeated to form the remaining layers in multilayer stack 22, until a desired topmost layer of multilayer stack 22 has been formed. In accordance with some embodiments, first layers 22A have thicknesses the same as or similar to each other, and second layers 22B have thicknesses the same as or similar to each other. First layers 22A may also have the same thicknesses as, or different thicknesses from, that of second layers 22B. In accordance with some embodiments, first layers 22A are removed in the subsequent processes, and are alternatively referred to as sacrificial layers 22A throughout the description. In accordance with alternative embodiments, second layers 22B are sacrificial, and are removed in the subsequent processes.

In accordance with some embodiments, there may be some pad oxide layer(s) and hard mask layer(s) (not shown) formed over multilayer stack 22. These layers are patterned, and are used for the subsequent patterning of multilayer stack 22.

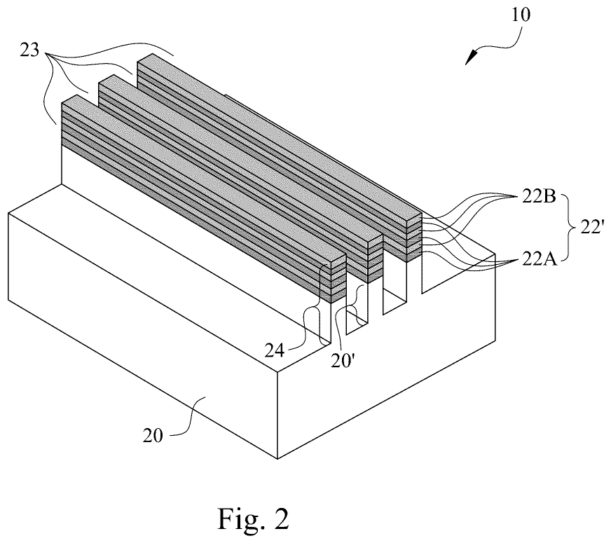

Referring to FIG. 2, multilayer stack 22 and a portion of the underlying substrate 20 are patterned in an etching process(es), so that trenches 23 are formed. The respective process is illustrated as process 204 in the process flow 200 shown in FIG. 27. Trenches 23 extend into substrate 20. The remaining portions of multilayer stacks are referred to as multilayer stacks 22′ hereinafter. Underlying multilayer stacks 22′, some portions of substrate 20 are left, and are referred to as substrate strips 20′ hereinafter. Multilayer stacks 22′ include semiconductor layers 22A and 22B. Semiconductor layers 22A are alternatively referred to as sacrificial layers, and Semiconductor layers 22B are alternatively referred to as nanostructures hereinafter. The portions of multilayer stacks 22′ and the underlying substrate strips 20′ are collectively referred to as semiconductor strips 24.

In above-illustrated embodiments, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

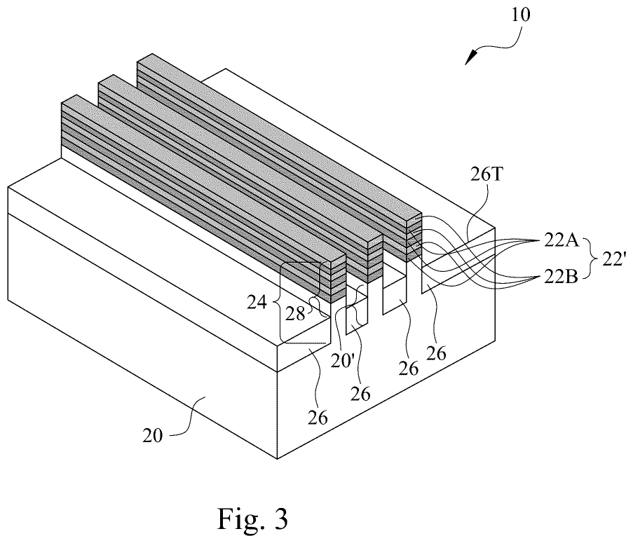

FIG. 3 illustrates the formation of isolation regions 26, which are also referred to as Shallow Trench Isolation (STI) regions throughout the description. The respective process is illustrated as process 206 in the process flow 200 shown in FIG. 27. STI regions 26 may include a liner oxide (not shown), which may be a thermal oxide formed through the thermal oxidation of a surface layer of substrate 20. The liner oxide may also be a deposited silicon oxide layer formed using, for example, ALD, High-Density Plasma Chemical Vapor Deposition (HDPCVD), CVD, or the like. STI regions 26 may also include a dielectric material over the liner oxide, wherein the dielectric material may be formed using Flowable Chemical Vapor Deposition (FCVD), spin-on coating, HDPCVD, or the like. A planarization process such as a Chemical Mechanical Polish (CMP) process or a mechanical grinding process may then be performed to level the top surface of the dielectric material, and the remaining portions of the dielectric material are STI regions 26.

STI regions 26 are then recessed, so that the top portions of semiconductor strips 24 protrude higher than the top surfaces 26T of the remaining portions of STI regions 26 to form protruding fins 28. Protruding fins 28 include multilayer stacks 22′ and the top portions of substrate strips 20′. The recessing of STI regions 26 may be performed through a dry etching process, wherein NF3 and NH3, for example, are used as the etching gases. During the etching process, plasma may be generated. Argon may also be included. In accordance with alternative embodiments of the present disclosure, the recessing of STI regions 26 is performed through a wet etching process. The etching chemical may include HF, for example.

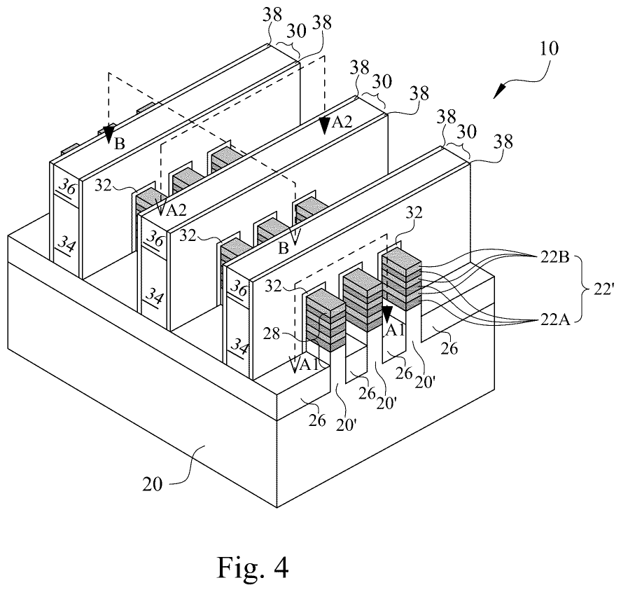

Referring to FIG. 4, dummy gate stacks 30 and gate spacers 38 are formed on the top surfaces and the sidewalls of (protruding) fins 28. The respective process is illustrated as process 208 in the process flow 200 shown in FIG. 27. Dummy gate stacks 30 may include dummy gate dielectrics 32 and dummy gate electrodes 34 over dummy gate dielectrics 32. Dummy gate dielectrics 32 may be formed by oxidizing the surface portions of protruding fins 28 to form oxide layers, or by depositing a dielectric layer such as a silicon oxide layer. Dummy gate electrodes 34 may be formed, for example, using polysilicon or amorphous silicon, and other materials such as amorphous carbon may also be used.

Each of dummy gate stacks 30 may also include one (or a plurality of) hard mask layer 36 over dummy gate electrode 34. Hard mask layers 36 may be formed of silicon nitride, silicon oxide, silicon carbo-nitride, silicon oxy-carbo nitride, or multilayers thereof. Dummy gate stacks 30 may cross over a single one or a plurality of protruding fins 28 and the STI regions 26 between protruding fins 28. Dummy gate stacks 30 also have lengthwise directions perpendicular to the lengthwise directions of protruding fins 28. The formation of dummy gate stacks 30 includes forming a dummy gate dielectric layer, depositing a dummy gate electrode layer over the dummy gate dielectric layer, depositing one or more hard mask layers, and then patterning the formed layers through a pattering process(es).

Next, gate spacers 38 are formed on the sidewalls of dummy gate stacks 30. In accordance with some embodiments of the present disclosure, gate spacers 38 are formed of a dielectric material such as silicon nitride (SiN), silicon oxide (SiO), silicon carbide (SiC), silicon oxide (SiO2), silicon carbo-nitride (SiCN), silicon oxynitride (SiON), silicon oxy-carbo-nitride (SiOCN), or the like, and may have a single-layer structure or a multilayer structure including a plurality of dielectric layers. The formation process of gate spacers 38 may include depositing one or a plurality of dielectric layers, and then performing an anisotropic etching process(es) on the dielectric layer(s). The remaining portions of the dielectric layer(s) are gate spacers 38.

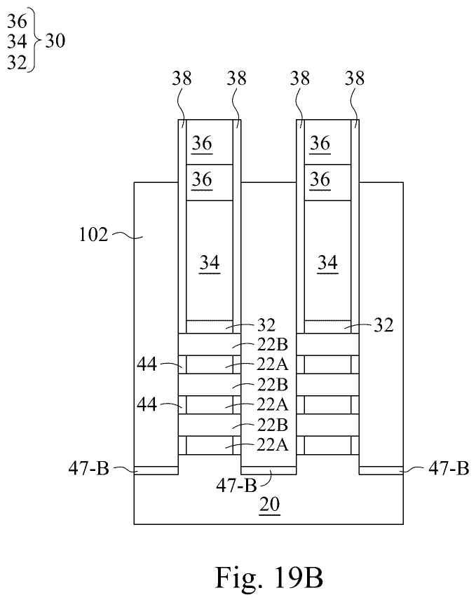

In accordance with alternative embodiments, one or more layers of gate spacers 38 may be formed using the processes as illustrated in FIG. 19, and the resulting layer of gate spacers 38 comprises the material as discussed referring to FIGS. 19 through 21. For example, gate spacers 38 may be formed of or include SiOCNH therein. The details of the formation processes are discussed in subsequent paragraphs.

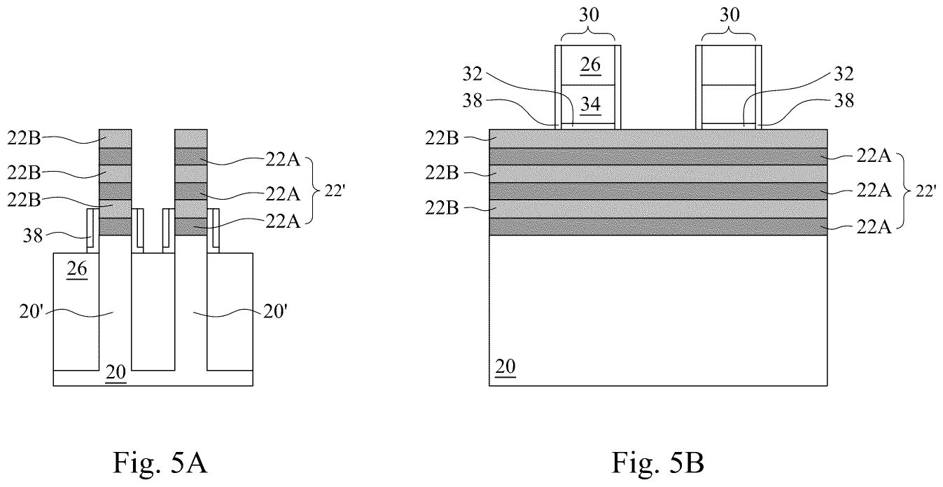

FIGS. 5A and 5B illustrate the cross-sectional views of the structure shown in FIG. 4. FIG. 5A illustrates the reference cross-section A1-A1 in FIG. 4, which cross-section cuts through the portions of protruding fins 28 not covered by gate stacks 30 and gate spacers 38, and is perpendicular to the gate-length direction. Fin spacers 38, which are on the sidewalls of protruding fins 28, are also illustrated. FIG. 5B illustrates the reference cross-section B-B in FIG. 4, which reference cross-section is parallel to the lengthwise directions of protruding fins 28.

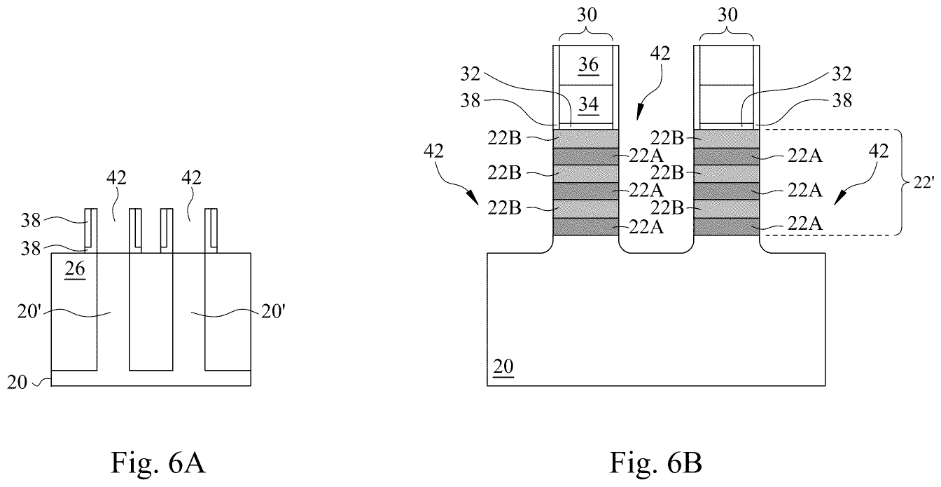

Referring to FIGS. 6A and 6B, the portions of protruding fins 28 that are not directly underlying dummy gate stacks 30 and gate spacers 38 are recessed through an etching process to form recesses 42. The respective process is illustrated as process 210 in the process flow 200 shown in FIG. 27. For example, a dry etch process may be performed using C₂F₆, CF₄, SO₂, the mixture of HBr, Cl₂, and O₂, the mixture of HBr, Cl₂, O₂, and CH₂F₂, or the like to etch multilayer semiconductor stacks 22′ and the underlying substrate strips 20′. The bottoms of recesses 42 are at least level with, or may be lower than (as shown in FIG. 6B), the bottoms of multilayer semiconductor stacks 22′. The etching may be anisotropic, so that the sidewalls of multilayer semiconductor stacks 22′ facing recesses 42 are vertical and straight, as shown in FIG. 6B.

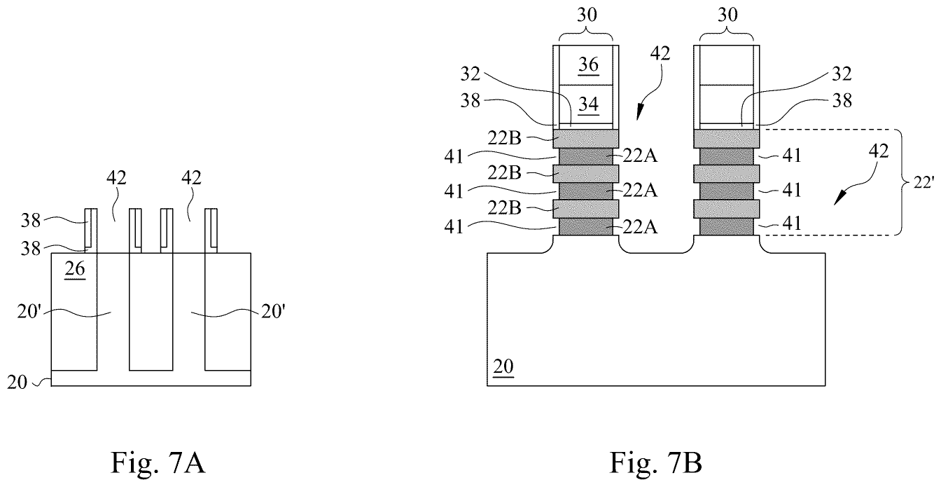

Referring to FIGS. 7A and 7B, sacrificial semiconductor layers 22A are laterally recessed to form lateral recesses 41, which are recessed from the edges of the respective overlying and underlying nanostructures 22B. The respective process is illustrated as process 212 in the process flow 200 shown in FIG. 27. The lateral recessing of sacrificial semiconductor layers 22A may be achieved through a wet etching process using an etchant that is more selective to the material (for example, silicon germanium (SiGe)) of sacrificial semiconductor layers 22A than the material (for example, silicon (Si)) of the nanostructures 22B and substrate 20. For example, in an embodiment in which sacrificial semiconductor layers 22A are formed of silicon germanium and the nanostructures 22B are formed of silicon, the wet etching process may be performed using an etchant such as hydrochloric acid (HCl). The wet etching process may be performed using a dip process, a spray process, a spin-on process, or the like.

In accordance with alternative embodiments, the lateral recessing of sacrificial semiconductor layers 22A is performed through an isotropic dry etching process or a combination of a dry etching process and a wet etching process.

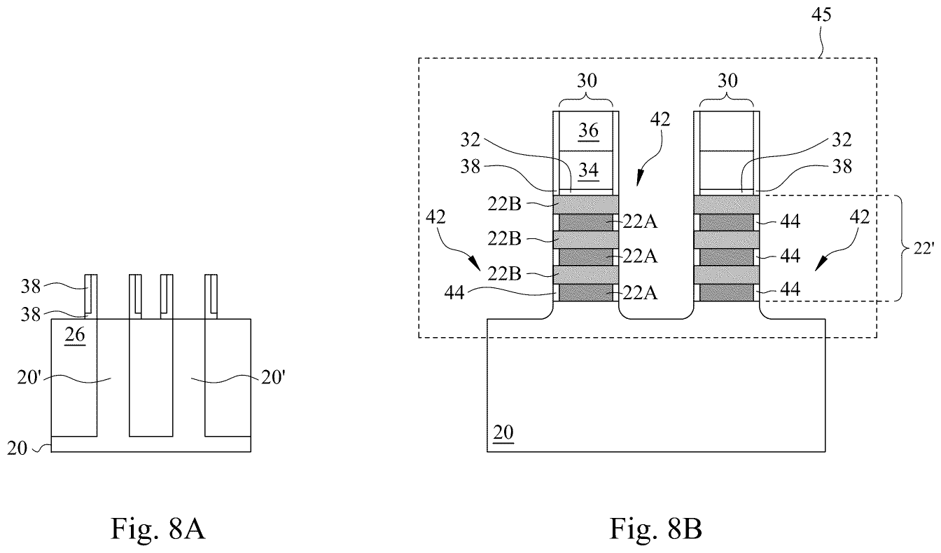

Referring to FIGS. 8A and 8B, inner spacers 44 are formed. The respective process is illustrated as process 214 in the process flow 200 shown in FIG. 27. In accordance with some embodiments, the formation of inner spacers 44 includes depositing a conformal dielectric layer, which extends into the lateral recesses 41 (FIG. 7B). Next, an etching process (also referred to as a spacer trimming process) is performed to trim the portions of the spacer layer outside of the lateral recesses 41, leaving the portions of the spacer layer in the lateral recesses 41. The remaining portions of the spacer layer are referred to as inner spacers 44.

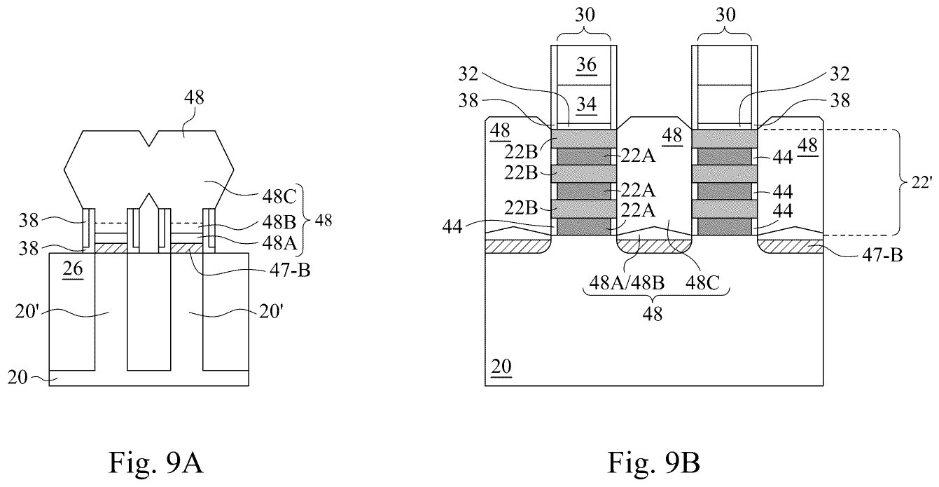

Referring to FIGS. 9A and 9B, dielectric layers 47-B and epitaxial source/drain regions 48 are formed in recesses 42. The respective process is illustrated as process 216 in the process flow 200 shown in FIG. 27. In accordance with some embodiments, the source/drain regions 48 may exert stress on the nanostructures 22B, which are used as the channels of the corresponding GAA transistors, thereby improving performance. Depending on whether the resulting transistor is a p-type transistor or an n-type transistor, a p-type or an n-type impurity may be in-situ doped with the proceeding of the epitaxy. For example, when the resulting transistor is a p-type Transistor, silicon germanium boron (SiGeB), silicon boron (SiB), or the like may be grown. Conversely, when the resulting transistor is an n-type Transistor, silicon phosphorous (SiP), silicon carbon phosphorous (SiCP), or the like may be grown.

After recesses 42 are filled with epitaxy regions 48, the further epitaxial growth of epitaxy regions 48 causes epitaxy regions 48 to expand horizontally, and facets may be formed. The further growth of epitaxy regions 48 may also cause neighboring epitaxy regions 48 to merge with each other. Voids (air gaps) may be generated under the merged epitaxy regions 48.

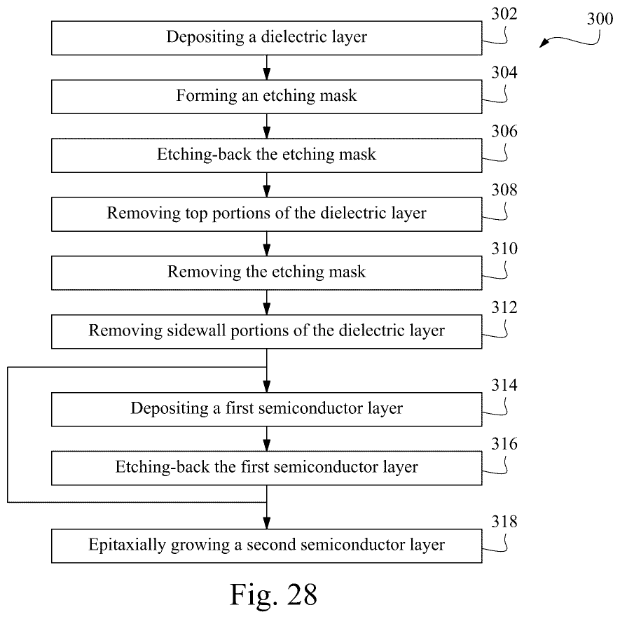

FIGS. 15-26 illustrate the details in the formation of the dielectric layers and source/drain regions (as shown in FIGS. 9A and 9B) in accordance with some embodiments. The processes shown in FIGS. 15-26 are also illustrated in the process flow 300 (which represents the process 216 in the process flow 200) as shown in FIG. 28. The illustrated region in FIG. 15 is the upper part of the structure shown in FIG. 8B.

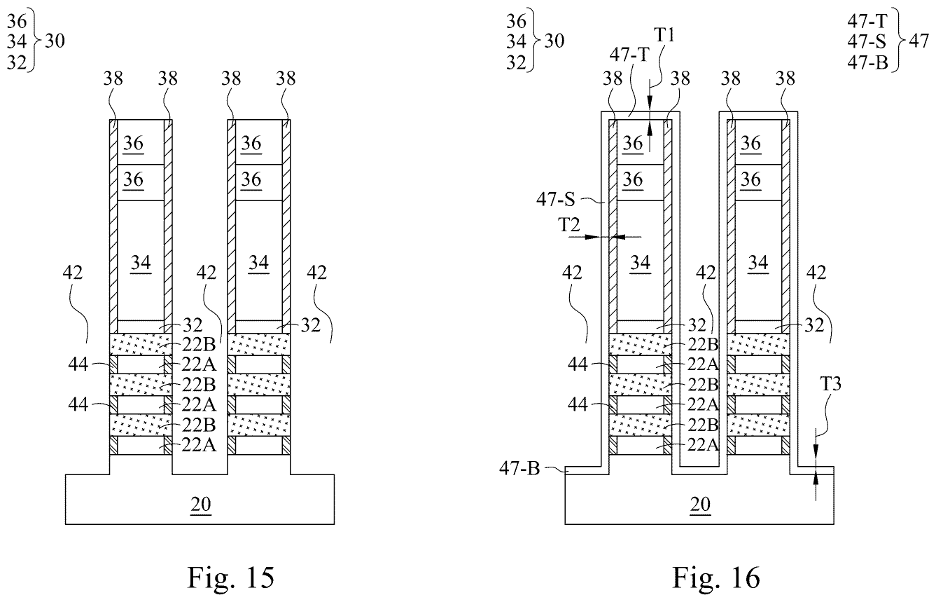

FIG. 15 illustrates the region 45 in FIG. 8B, in which recesses 42 and inner spacers 44 have been formed. Next, FIGS. 16 through 20 illustrate the selective formation of dielectric layers 47-B at the bottom of recesses 42 in accordance with various embodiments. Referring to FIG. 16, dielectric layer 47 is deposited. The respective process is illustrated as process 302 in the process flow 300 shown in FIG. 28. In accordance with some embodiments, dielectric layer 47 comprises silicon nitride (SiN). The process gas may include silane (SiH₄), ammonia (NH₃), and the like. Dielectric layer 47 may also be formed of or comprise silicon oxide (SiO), silicon carbide (SiC), silicon oxynitride (SiON), silicon carbo-nitride (SiCN), silicon oxy carbo-nitride (SiOCN), or the like.

In accordance with some embodiments, dielectric layer 47 is deposited using a directional deposition process, which includes both of anisotropic component and isotropic component. Accordingly, dielectric layer 47 includes top portions 47-T, sidewall portions 47-S, and bottom portions 47-B. The thickness T1 of the top portions 47-T, the thickness T2 of the sidewall portions 47-S, and the thickness T3 of the bottom portions 47-B are different from each other. For example, thickness T1 may be greater than thickness T2. In accordance with some embodiments, the deposition of dielectric layer 47 may include Plasma-Enhanced Atomic Layer Deposition (PEALD), Plasma-Enhanced Chemical Vapor Deposition (PECVD), or the like. In the deposition process, bias power is applied to generate the directional (anisotropic) effect. In accordance with some embodiments, the bias power is greater than about 50 watts, and may be in the range between about 50 watts and about 500 watts.

The composition (the elements and the percentages of the elements) of the sidewall portions 47-S may be different from that of the top portions 47-T and the bottom portions 47-B. For example, when NH₃-based precursors are used, the NH₃-based precursors tend to be adsorbed on the sidewalls of recesses 42 than on the tops of gate stacks 30 and at the bottoms of recesses 42. Accordingly, the composition of sidewall portions 47-S may comprise a higher atomic percentage of the NH₃-based compound (for example, with more N and/or H) than the top portions 47-T and the bottom portions 47-B. The properties of the sidewall portions 47-S are thus different from the properties of the top portions 47-T and the bottom portions 47-B.

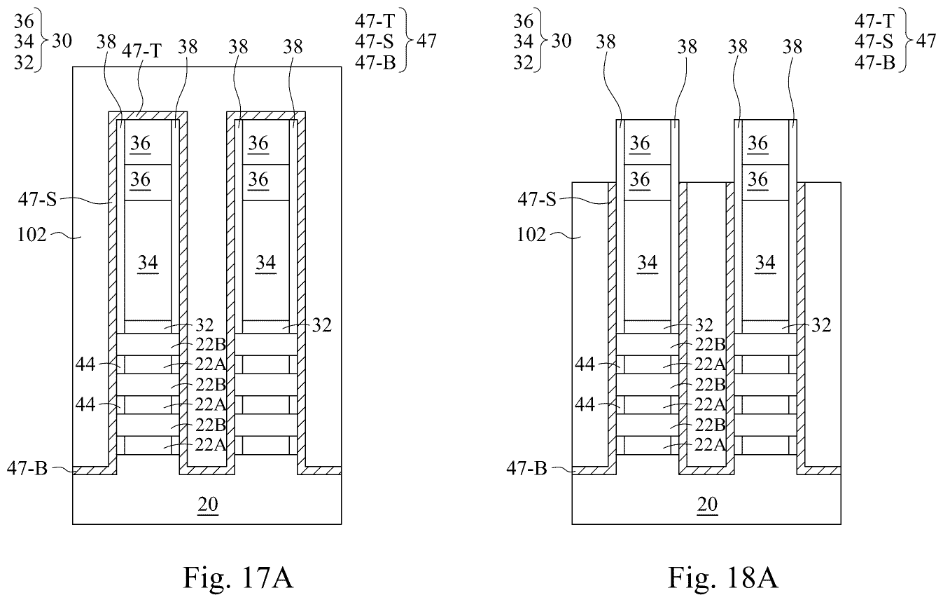

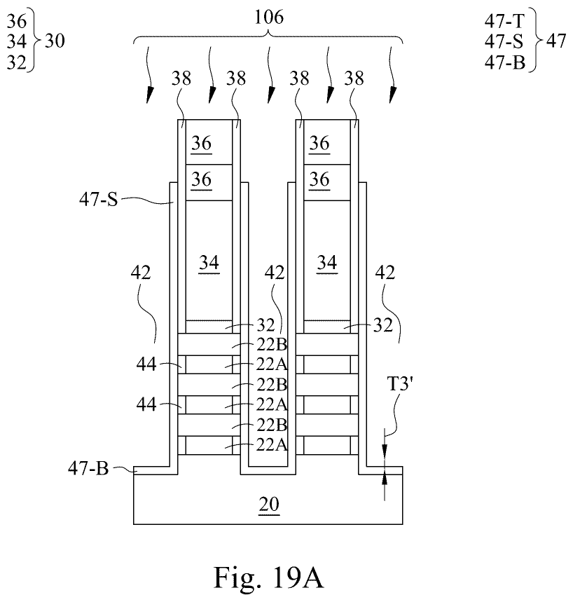

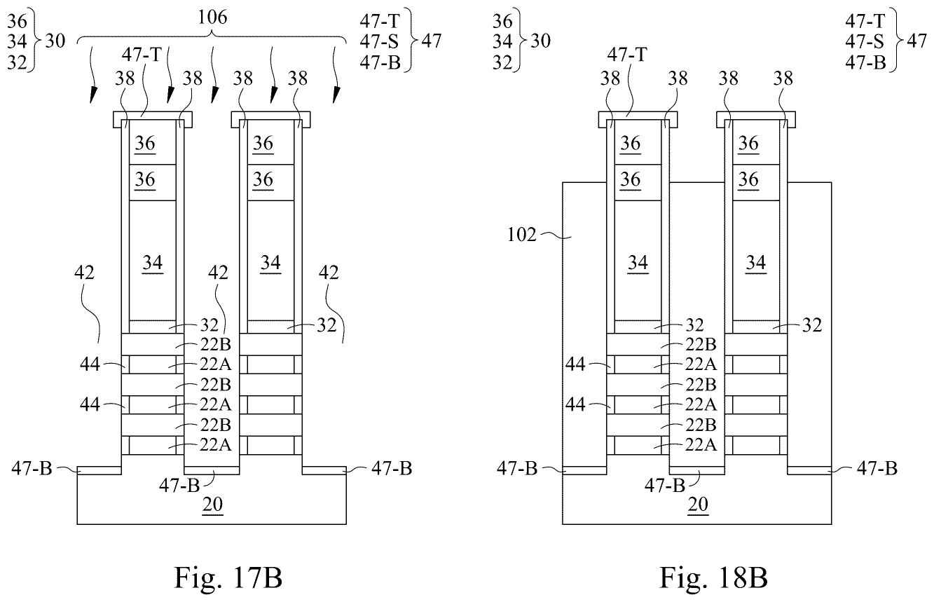

In subsequent processes, the top portions 47-T and sidewall portions 47-S are selectively removed, while the bottom portions 47-B are selectively left at the bottom of recesses 42. The selective removal of the top portions 47-T and sidewall portions 47-S may be achieved using the processes shown in FIGS. 17A, 18A, and 19A, or may be achieved using the processes shown in FIGS. 17B, 18B, and 19B.

FIGS. 17A, 18A, and 19A illustrate the processes in which top portions 47-T are removed before the removal of the sidewall portions 47-S in accordance with some embodiments. Referring to FIG. 17A, etching mask 102 is formed. The respective process is illustrated as process 304 in the process flow 300 shown in FIG. 28. In accordance with some embodiments, etching mask 102 comprises a photoresist (which may be cross-linked), while other materials that have enough etching selectivity relative to the underlying features may be adopted. Etching mask 102 may be applied through spin-on coating, while other processes may be used, depending on the material of etching mask 102. There may be, or may not be, a planarization process (such as a mechanical polish process) performed to further level the top surface of etching mask 102.

Etching mask 102 is etched back, so that the top surface of etching mask 102 is lower than the top portions 47-T. The respective process is illustrated as process 306 in the process flow 300 shown in FIG. 28. In a subsequent process, an etching process is performed to remove the top portions 47-T. The resulting structure is shown in FIG. 18A. The respective process is illustrated as process 308 in the process flow 300 shown in FIG. 28. The etching may be isotropic or anisotropic. The top part of the sidewall portions 47-S may be, or may not be, removed, depending on whether isotropic etching or anisotropic etching is used. For example, if anisotropic etching is used, some of the top parts of the sidewall portions 47-S may remain, or may be thinned, but not removed.

Etching mask 102 is then removed, for example, in an ashing process or an etching process. The respective process is illustrated as process 310 in the process flow 300 shown in FIG. 28. The sidewall portions 47-S and bottom portions 47-B are thus exposed, as shown in FIG. 19A. An isotropic etching process 106 is then performed to remove the sidewall portions 47-S. The respective process is illustrated as process 312 in the process flow 300 shown in FIG. 28. The etching is performed using a chemical (a wet etching solution or an etching gas) that etches the sidewall portions 47-S faster than the bottom portions 47-B. For example, when the NH₃-based precursor is used to deposit dielectric layer 47, the etching may be performed using an etching gas comprising CF₄, NF₃, SF₆, CHF₃, CIF₃, and/or the like, or combinations thereof. Alternatively, the etching may be performed using a wet etching solution comprising, for example H₂SO₄.

The sidewall portions 47-S are etched faster than the bottom portions 47-B, for example, due to that different compositions of the sidewall portions 47-S and the bottom portions 47-B. Also, the bottom portions 47-B is at the bottom of recesses 42, again contributing to the lower etching rate than sidewall portions 47-S. Accordingly, after the etching, the bottom portions 47-B of dielectric layer 47 remain. The thickness T3′ of bottom portions 47-B may be in the range between about 1 nm and about 5 nm, and may be in the range between about 3 nm and about 5 nm.

FIGS. 17B, 18B, and 19B illustrate an alternative process for removing the top portions 47-T and the sidewall portions 47-S, in which top portions 47-T are removed after the removal of sidewall portions 47-S. The process shown in FIG. 17B continues from the process in FIG. 16. Referring to FIG. 17B, etching process 106 is performed to remove the sidewall portions 47-S of dielectric layer 47, while the top portions 47-T and bottom portions 47-B are thinned, but not removed. Etching process 106 may be isotropic.

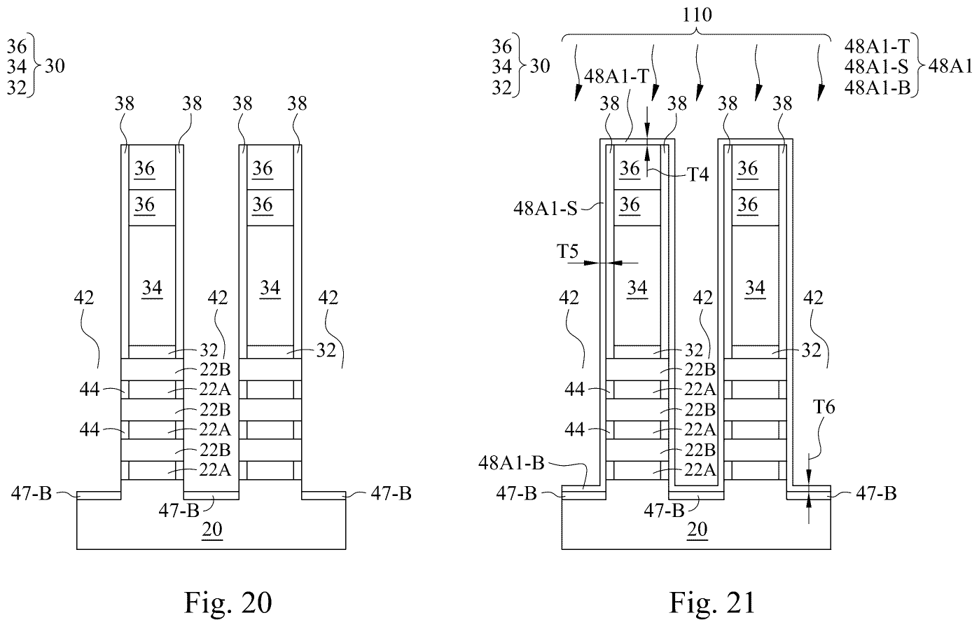

FIG. 18B illustrates the formation of etching mask 102, which has a top surface lower than the top portions 47-T of dielectric layer 47. Next, the top portions 47-T are removed in an etching process, which may be isotropic or anisotropic. The resulting structure is shown in FIG. 19B. In a subsequent process, etching mask 102 is removed, and the resulting structure is also shown in FIG. 20.

FIGS. 21 through 24 illustrate the selective formation of semiconductor layer 48A, which is an amorphous semiconductor layer. The selective formation process includes a plurality of cycles, each including a deposition process and an etch-back process. The plurality of cycles are also referred to as deposition-and-etch cycles. Referring to FIG. 21, semiconductor layer 48A1 is deposited. The respective process is illustrated as process 314 in the process flow 300 shown in FIG. 28. In accordance with some embodiments, semiconductor layer 48A1 is deposited as an amorphous layer. The deposition process may be performed using a directional (with both of anisotropic component and isotropic component) deposition process. In accordance with some embodiments, the deposition of semiconductor layer 48A1 may include PECVD or a like-process.

In the deposition process, bias power is applied to generate the directional (anisotropic) effect. The bias power cannot be too high. Otherwise, the formation of the bottom portions 48A1-B suffers from problems. The bias power also cannot be too low. Otherwise, the sidewall portions 48A1-S will be too thick, and will be difficult to be removed in subsequent process. In accordance with some embodiments, the bias power is greater than about 50 watts, and may be in the range between about 50 watts and about 500 watts.

In the deposition process, the sidewall portions 48A1-S of semiconductor layer 48A1 are thinner than the top portions 48A1-T overlapping gate stacks 30 and the bottom portions 48A1-B overlapping dielectric layers 47-B. In accordance with some embodiments, the top thickness T4 of the top portions 48A1-T is greater than the bottom thickness T6 of the bottom portions 48A1-B, and the bottom thickness T6 is further greater than the sidewall thickness T5 of the sidewall portions 48A1-S.

In accordance with some embodiments, semiconductor layer 48A1 comprises Si, SiGe, SiC, SiP, or the like, with a desirable p-type or n-type dopant such as boron or phosphorous doped. In accordance with some embodiments, semiconductor layer 48A1 comprises Si, SiGe, SiC, or the like, with no p-type and n-type dopant doped. In accordance with some embodiments, the deposition is performed using PECVD (for example, adopting capacitively coupled plasma (CCP)). The precursors may include silane (SiH₄), SiH₂Cl₂, NH₃, N₂, Ar, and/or the like, and with plasma being used to dissociate silane. The temperature of the respective wafer may be in the range between about 300° C. and about 400° C. The resulting intermediate composition during the dissociation may include radicals (such as SiH₃, SiH₂, and SiH), and may or may not include ions (such as SiH₃⁺, SiH₂⁺, and SiH⁺). Electrons (e⁻) react with the SiH₄ and the intermediate products to dissociate the silane and the intermediate products, until silicon is deposited.

In accordance with some embodiments, the deposition of semiconductor layer 48A1 may be performed with a flow rate of SiH₄ in the range between about 25 sccm and about 150 sccm. Hydrogen (H₂) may be or may not be conducted. When hydrogen is conducted, the flow rate may be in the range between about 1,000 sccm and about 5,000 sccm. The pressure of the deposition chamber may be in the range between about 0.8 torr and about 1.2 torr.

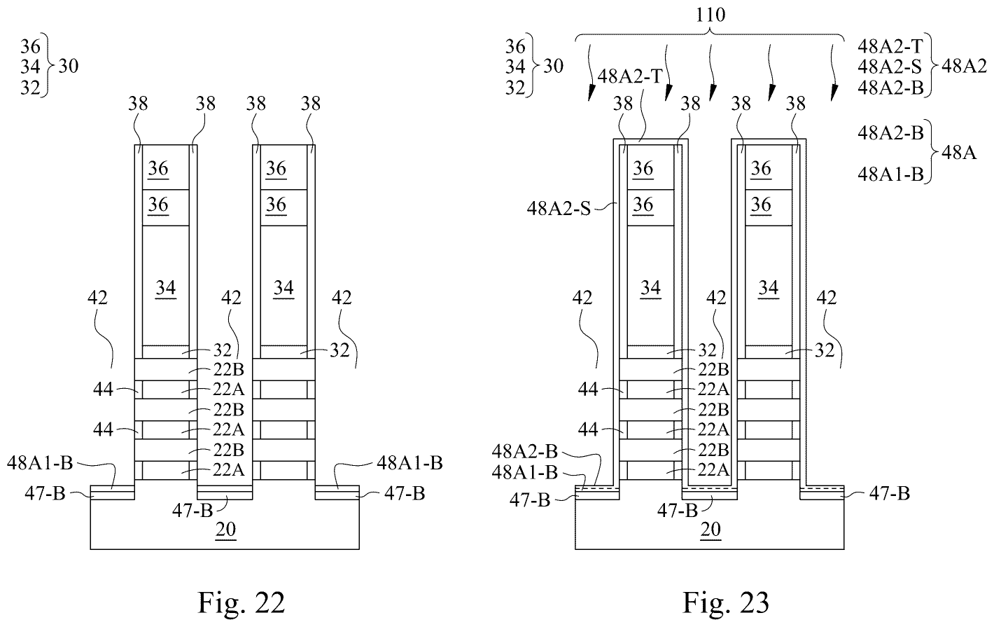

After the deposition of semiconductor layer 48A1, etch-back process 110 is performed to etch-back semiconductor layer 48A1, and to remove top portions 48A1-T and sidewall portions 48A1-S. The respective process is illustrated as process 316 in the process flow 300 shown in FIG. 28. The resulting structure is shown in FIG. 22. The bottom portions 48A1-B has some portions remaining, although it is thinned. In accordance with some embodiments, the aspect ratio of recesses 42 are selected to be big, so that when the top portions 48A1-T and sidewall portions 48A1-S are removed, the bottom portions 48A1-B still has some portions remaining. On the other hand, the aspect ratio cannot be too big. Otherwise, the bottom portions 48A1-B may be too thin when it is deposited, and will also be removed. In accordance with some embodiments, the aspect ratio of recesses 42 is in the range between about 5 and about 15.

In accordance with some embodiments, the etch-back process 110 is performed using hydrogen (H₂) as the etching gas, with a plasma etching process and/or a thermal etching process being performed. In accordance with some embodiments, the reaction formula may be Si(s)+2H₂(g)-->SiH₄(g), wherein the symbol “s” indicates that Si is the solid in semiconductor layer 48A1, and the symbol “g” indicates that hydrogen gas and silane gas are gases.

In accordance with some embodiments, the etch-back process 110 of semiconductor layer 48A1 may be performed with a flow rate of hydrogen (H₂) in the range between about 1,000 sccm and about 5,000 sccm. The pressure in the corresponding etching chamber may be in the range between about 1 torr and about 5 torr, and may be in the range between about 2 torr and about 3 torr.

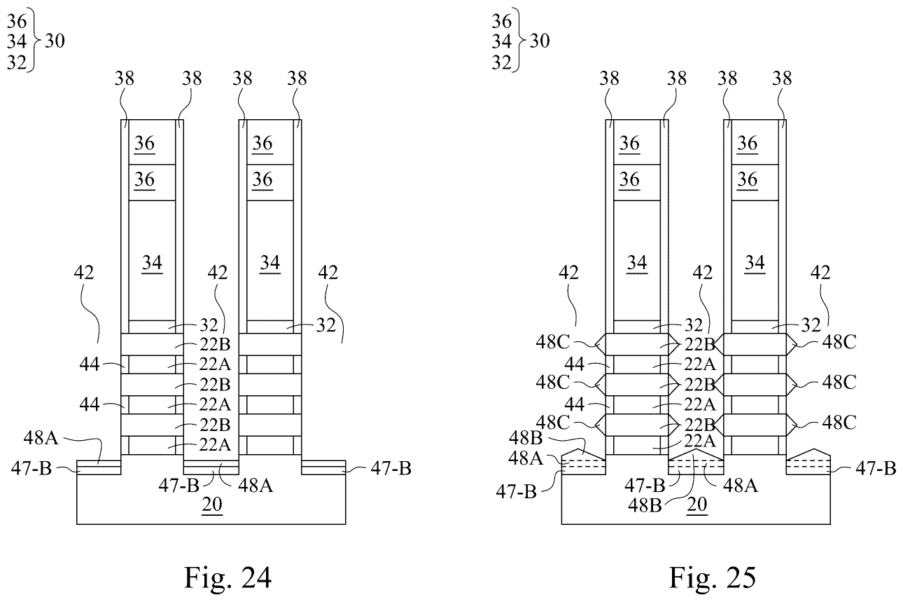

FIGS. 23 and 24 illustrate another deposition-and-etch cycle of semiconductor layer 48A2. The respective process is illustrated in FIG. 28 as looping back from the end of process 316 to process 314. The bottom portion 48A2-B of semiconductor layer 48A2 is deposited on the remaining bottom portion 48A1-B. The materials, the structures, and the processes of the embodiments regarding FIGS. 23 and 24 may be essentially the same as that in FIGS. 21 and 22, respectively, and are not repeated herein. As a result of the processes in FIGS. 23 and 24, the bottom portion 48A2-B of semiconductor layer 48A2 is left on bottom portion 48A1-B. Throughout the description, the bottom portions of the semiconductor layers 48A1, 48A2, and the like at the bottoms of recesses 42 are collectively referred to as semiconductors 48A. The thickness of the resulting semiconductor layer 48A, as shown in FIG. 24, is thus increased by the second deposition-and-etch cycle.

In accordance with some embodiments, no void is formed between semiconductor layer 48A and the respective underlying dielectric layers 47-B. The interface between a semiconductor layer 48A and the respective underlying dielectric layers 47-B may extend all the way from the left end of the corresponding recess 42 all the way to the right end of the recess 42. Also, the entire top surface of dielectric layer 47-B may be covered by, and in contact with, semiconductor layer 48A.

After the second deposition-and-etch cycle, more deposition-and-etch cycles may be performed. Each of the deposition-and-etch cycles causes the increase in the thickness of the semiconductor layer 48A. The total number of deposition-and-etch cycles may be in the range between about 1 cycle and about 5 cycles, and may be between about 3 cycles and about 5 cycles. The total time of all of the deposition-and-etch cycles may range between about 10 minutes and about 1 hour. The total thickness of semiconductor layer 48A may be in the range between about 1 nm and about 5 nm.

FIG. 25 illustrates a second deposition process (which includes an epitaxy process) to further deposit semiconductor layers 48B. The respective process is illustrated as process 318 in the process flow 300 shown in FIG. 28. In accordance with some embodiments, the second deposition process is performed with a different process and different process conditions than the first deposition processes (which are used for the deposition-and-etch cycles). For example, the second deposition process may not include etch-back process therein, regardless of the number of deposition processes and the number of sub layers in the second deposition process. The second deposition process may also be a continuous deposition process (with no break therein).

Furthermore, the second deposition process may be more isotropic than the first deposition process as shown in FIGS. 21 and 23. In accordance with some embodiments, the second deposition process may be performed through CVD, without plasma being generated. The second deposition process may also be performed through CVD with plasma. In accordance with some embodiments, no bias power is applied in the second deposition process.

The material of semiconductor layers 48B may be selected from the same group of candidate materials of semiconductor layers 48A, and may be the same as or different from the material of semiconductor layers 48A. Semiconductor layers 48B may also comprises Si, SiGe, SiC, SiP, or the like, and may be doped with a p-type dopant such as boron, indium or the like, or an n-type dopant such as phosphorous, arsenic, and/or the like.

The second deposition process is performed at a high (wafer) temperature that enables the generation of crystalline structures, and the temperature may be higher than the temperature for depositing semiconductor layers 48A. In accordance with some embodiments, the second deposition process is performed at a temperature in the range between about 500° C. and about 700° C. Since semiconductor layer 48B is deposited on amorphous semiconductor layer 48A. Semiconductor layers 48B, may also be amorphous. The amorphous semiconductor layers 48A and 48B are collectively referred to as semiconductor layers 48a.

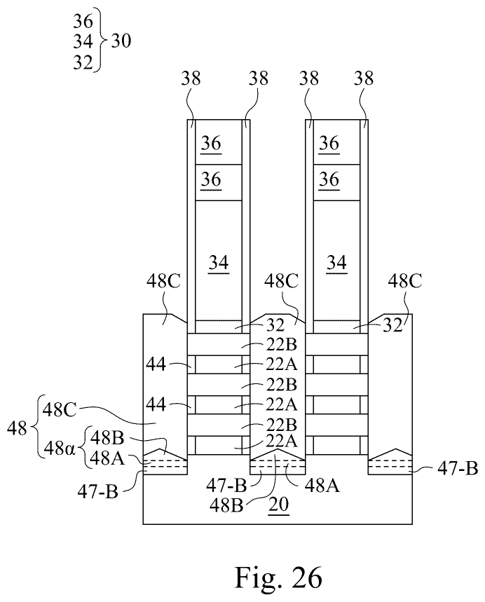

At the same time semiconductor layers 48B are deposited, semiconductor layers 48C may be epitaxially grown from nanostructures 22B. Next, FIG. 26 illustrates the structure formed by the continued second deposition process. It is appreciated that the processes shown in FIGS. 25 and 26 may be parts of the same deposition process that has no break in between and no change in process conditions. Through the continued deposition, semiconductor layer 48C, which is crystalline, fills the entire recesses 42, and may grow to a level higher than the top nanostructure 22B.

It is appreciated that the bottom portion of semiconductor layer 48C and amorphous semiconductor layer 48B may have a gradually transitioned layer in between, and the gradually transitioned layer gradually transitions from amorphous to polysilicon, and then to crystalline, which transition portion is not shown herein. The formation of dielectric layers 47-B and source/drain regions 48 is thus finished.

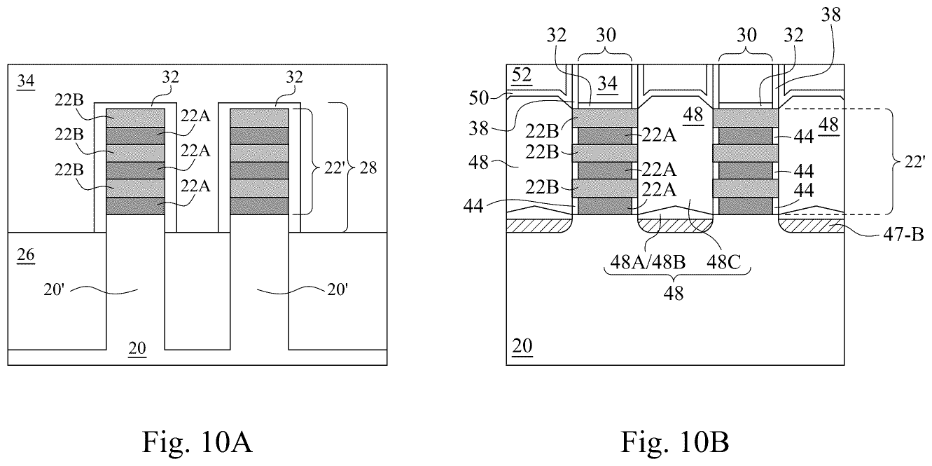

FIGS. 10A and 10B through FIGS. 14A and 14B illustrate the subsequent processes. These figures may have the corresponding numbers followed by letter A or B. The figure with the figure number having the letter A indicates that the corresponding figure shows a reference cross-section same as the reference cross-section A2-A2 in FIG. 4. The figure with the figure number having the letter B indicates that the corresponding figure shows a reference cross-section same as the reference cross-section B-B in FIG. 4.

FIGS. 10A and 10B illustrate the cross-sectional views of the structure after the formation of Contact Etch Stop Layer (CESL) 50 and Inter-Layer Dielectric (ILD) 52. The respective process is illustrated as process 218 in the process flow 200 shown in FIG. 27. CESL 50 may be formed of silicon oxide, silicon nitride, silicon carbo-nitride, or the like, and may be formed using CVD, ALD, or the like. ILD 52 may include a dielectric material formed using, for example, FCVD, spin-on coating, CVD, or any other suitable deposition method. ILD 52 may be formed of an oxygen-containing dielectric material, which may be a silicon-oxide based material formed using Tetra Ethyl Ortho Silicate (TEOS) as a precursor, Phospho-Silicate Glass (PSG), Boro-Silicate Glass (BSG), Boron-Doped Phospho-Silicate Glass (BPSG), Undoped Silicate Glass (USG), or the like.

CESL 50 and ILD 52 are planarized through a planarization process such as a CMP process or a mechanical grinding process. The respective process is illustrated as process 220 in the process flow 200 shown in FIG. 27. In accordance with some embodiments, the planarization process may remove hard masks 36 to reveal dummy gate electrodes 34, as shown in FIG. 10A. In accordance with alternative embodiments, the planarization process may reveal, and is stopped on, hard masks 36. In accordance with some embodiments, after the planarization process, the top surfaces of dummy gate electrodes 34 (or hard masks 36), gate spacers 38, and ILD 52 are level within process variations.

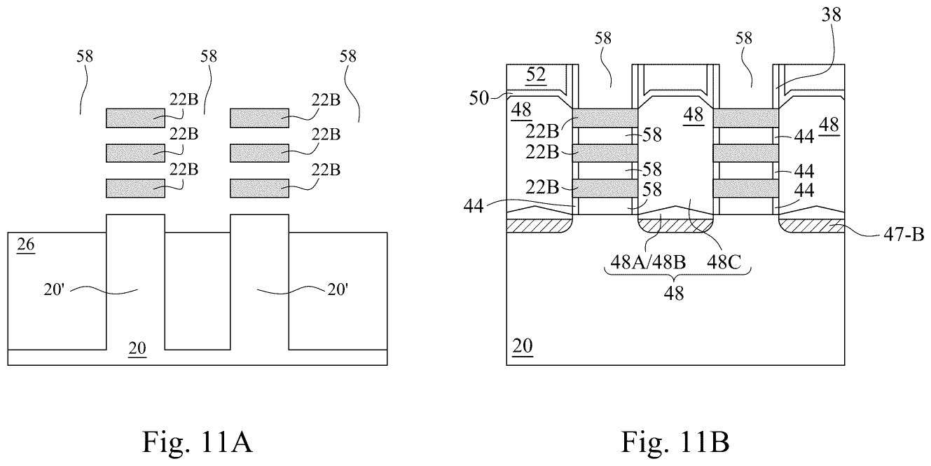

Next, dummy gate electrodes 34 and dummy gate dielectrics 32 (and hard masks 36, if remaining) are removed in one or more etching processes, so that recesses 58 are formed, as shown in FIGS. 11A and 11B. The respective process is illustrated as process 222 in the process flow 200 shown in FIG. 27. In accordance with some embodiments, dummy gate electrodes 34 and dummy gate dielectrics 32 are removed through an anisotropic dry etch process(es). For example, the etching process may be performed using reaction gas(es) that selectively etch dummy gate electrodes 34 and dummy gate dielectrics 32 at faster rates than ILD 52. Each recess 58 exposes and/or overlies portions of multilayer stacks 22′, which include the future channel regions in subsequently completed transistors.

Sacrificial layers 22A are then removed to extend recesses 58 between nanostructures 22B. The respective process is illustrated as process 224 in the process flow 200 shown in FIG. 27. Sacrificial layers 22A may be removed by performing an isotropic etching process such as a wet etching process using etchants which are selective to the materials of sacrificial layers 22A, while nanostructures 22B, substrate 20, and STI regions 26 remain relatively un-etched as compared to sacrificial layers 22A. In accordance with some embodiments in which sacrificial layers 22A include, for example, SiGe, and nanostructures 22B include, for example, Si or SiC, tetra methyl ammonium hydroxide (TMAH), ammonium hydroxide (NH4OH), or the like may be used to remove sacrificial layers 22A.

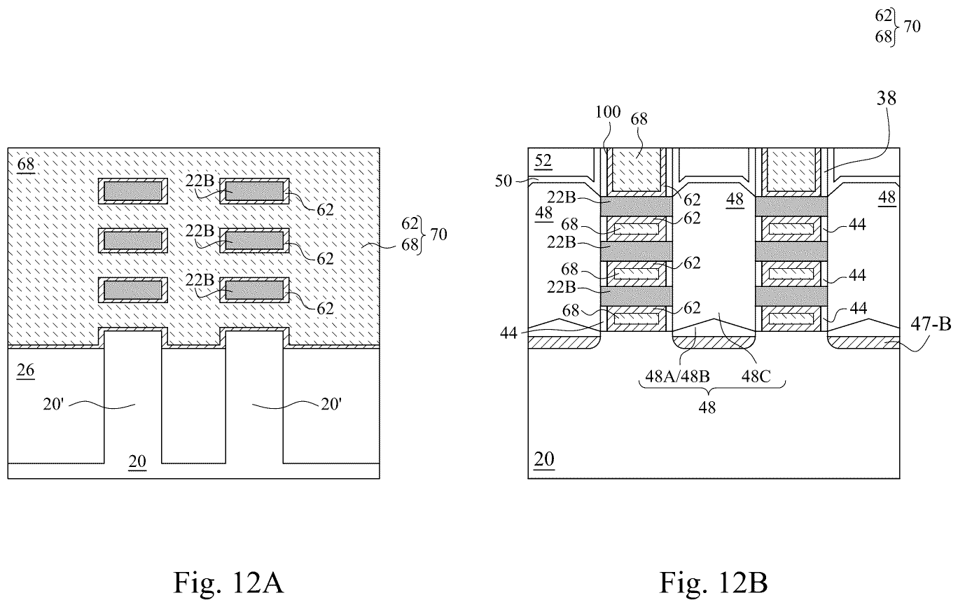

Referring to FIGS. 12A and 12B, gate dielectrics 62 and gate electrodes 68 are formed, hence forming replacement gate stacks 70. The respective process is illustrated as process 226 in the process flow 200 shown in FIG. 27. In accordance with some embodiments, each of gate dielectric 62 includes an interfacial layer and a high-k dielectric layer on the interfacial layer. The interfacial layer may be formed of or comprises silicon oxide, which may be deposited through a conformal deposition process such as ALD or CVD, or through an oxidation process. In accordance with some embodiments, the high-k dielectric layers comprise one or more dielectric layers. For example, the high-k dielectric layer(s) may include a metal oxide or a silicate of hafnium, aluminum, zirconium, lanthanum, manganese, barium, titanium, lead, and combinations thereof.

Gate electrodes 68 are also formed. In the formation, conductive layers are first formed on the high-k dielectric layer, and the remaining portions of recesses 58 are filled. Gate electrodes 68 may include a metal-containing material such as TiN, TaN, TiAl, TiAlC, cobalt, ruthenium, aluminum, tungsten, combinations thereof, and/or multilayers thereof. For example, gate electrodes 68 may comprise any number of layers, any number of work function layers, and possibly a filling material. Gate dielectrics 62 and gate electrodes 68 also fill the spaces between adjacent ones of nanostructures 22B, and fill the spaces between the bottom ones of nanostructures 22B and the underlying substrate strips 20′. After the filling of recesses 58, a planarization process such as a CMP process or a mechanical grinding process is performed to remove the excess portions of the gate dielectrics and the material of gate electrodes 68, which excess portions are over the top surface of ILD 52. Gate electrodes 68 and gate dielectrics 62 are collectively referred to as gate stacks 70 of the resulting transistors.

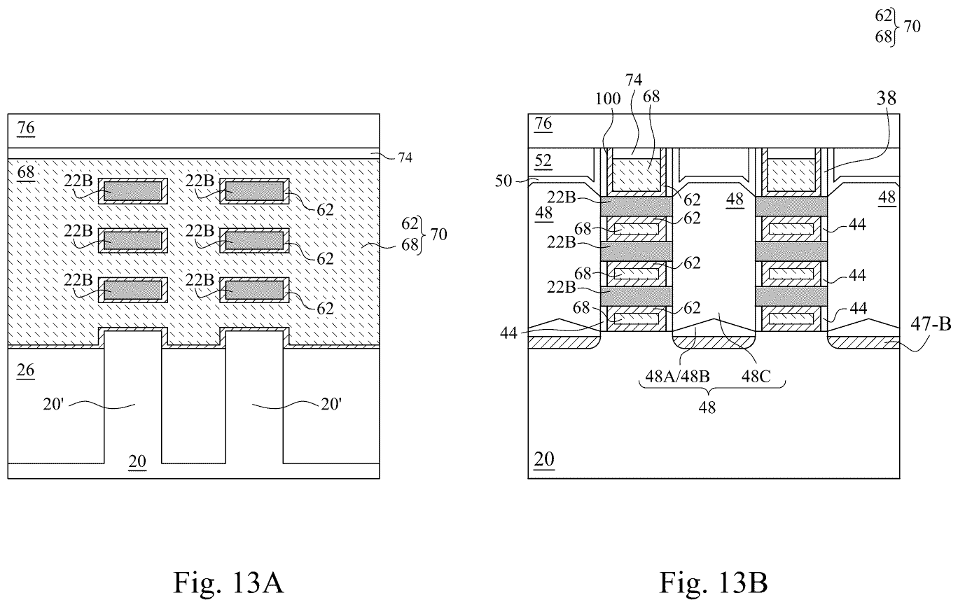

In the processes shown in FIGS. 13A and 13B, gate stacks 70 are recessed, so that recesses are formed directly over gate stacks 70 and between opposing portions of gate spacers 38. A gate mask 74 comprising one or more layers of dielectric material, such as silicon nitride, silicon oxynitride, or the like, is filled in each of the recesses, followed by a planarization process to remove excess portions of the dielectric material extending over ILD 52. The respective process is illustrated as process 228 in the process flow 200 shown in FIG. 27.

As further illustrated by FIGS. 13A and 13B, ILD 76 is deposited over ILD 52 and over gate masks 74. The respective process is illustrated as process 230 in the process flow 200 shown in FIG. 27. An etch stop layer (not shown), may be, or may not be, deposited before the formation of ILD 76. In accordance with some embodiments, ILD 76 is formed through FCVD, CVD, PECVD, or the like. ILD 76 is formed of a dielectric material, which may be selected from silicon oxide, PSG, BSG, BPSG, USG, or the like.

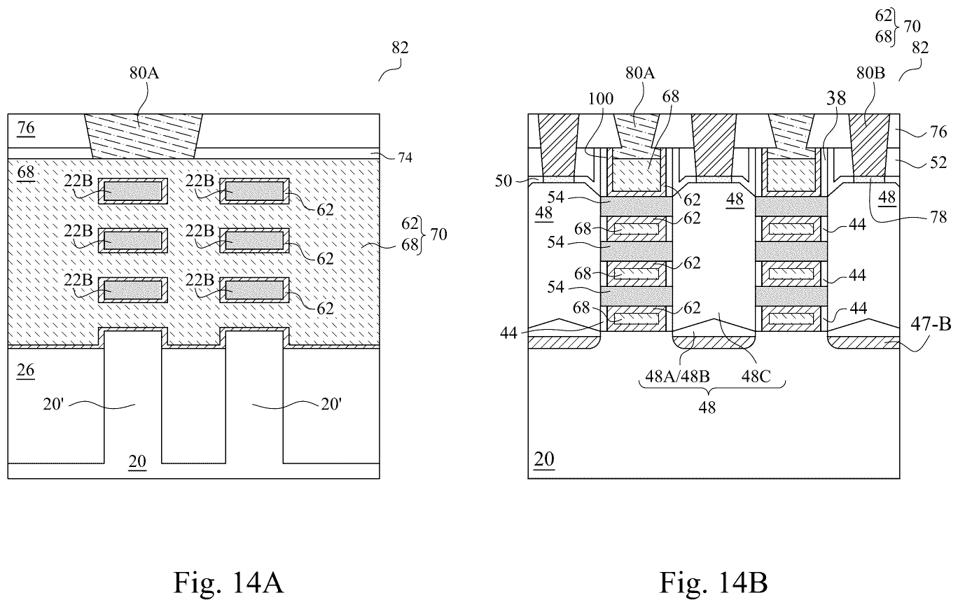

In FIGS. 14A and 14B, ILD 76, ILD 52, CESL 50, and gate masks 74 are etched to form recesses (occupied by contact plugs 80A and 80B) exposing surfaces of source/drain regions 48 and/or gate stacks 70. The recesses may be formed through etching using an anisotropic etching process, such as RIE, NBE, or the like. Although FIG. 14B illustrates that contact plugs 80A and 80B are in a same cross-section, in various embodiments, contact plugs 80A and 80B may be formed in different cross-sections, thereby reducing the risk of shorting with each other.

After the recesses are formed, silicide regions 78 are formed over source/drain regions 48. The respective process is illustrated as process 232 in the process flow 200 shown in FIG. 27. Contact plugs 80B are then formed over silicide regions 78. Also, contacts 80A (may also be referred to as gate contact plugs) are also formed in the recesses, and are over and contacting gate electrodes 68. The respective process is illustrated as process 234 in the process flow 200 shown in FIG. 27. Transistor 82 is thus formed.

The embodiments of the present disclosure have some advantageous features. By selectively forming semiconductor layers over the dielectric layers that are formed at the bottoms of recesses (for source/drain regions), no void is generated in source/drain regions and in between the dielectric layers and the source/drain regions. As a comparison, if epitaxy processes are directly performed to grow the source/drain regions on the dielectric layers, voids will be generated on the dielectric layers, which will adversely relax strains applied by the source/drains on channels.

In accordance with some embodiments of the present disclosure, a method comprises etching a semiconductor region aside of a gate stack to form a recess; forming a dielectric layer at a bottom of the recess; selectively forming a first semiconductor layer at the bottom of the recess, wherein a bottom surface of the first semiconductor layer forms an interface with a top surface of the dielectric layer, with the interface extending to opposing sides of the recess, and wherein the selectively forming the first semiconductor layer comprises a first deposition process performed under first process conditions; and epitaxially growing a second semiconductor layer on the first semiconductor layer, wherein the epitaxially growing the second semiconductor layer is performed using a second deposition process under second process conditions, and wherein the second process conditions are different from the first process conditions.

In an embodiment, the selectively forming the first semiconductor layer comprises a first deposition-and-etch cycle comprising the first deposition process to deposit a sub layer of the first semiconductor layer, wherein the sub layer comprises a top portion overlapping the gate stack; a sidewall portion on a sidewall of the semiconductor region, with the sidewall being in the recess; and a bottom portion at the bottom of the recess; and an etch-back process to remove the top portion and the sidewall portion, with a part of the bottom portion remaining. In an embodiment, the selectively forming the first semiconductor layer further comprises a second deposition-and-etch cycle after the first deposition-and-etch cycle. In an embodiment, the etch-back process is performed by exposing all of the top portion, the sidewall portion, and the bottom portion to an etching chemical. In an embodiment, the second deposition process is a continuous process, and the continuous process is performed until the recess is substantially fully filled.

In an embodiment, the first deposition process is a directional deposition process that is performed with a bias power applied. In an embodiment, the second deposition process is performed without bias power applied. In an embodiment, the first deposition process is performed using plasma enhance chemical vapor deposition, and the second deposition process is performed using chemical vapor deposition. In an embodiment, the first semiconductor layer is amorphous, and the second semiconductor layer comprises a crystalline portion. In an embodiment, the first semiconductor layer is formed at a first deposition temperature, and the second semiconductor layer is deposited at a second temperature higher than the first deposition temperature.

In accordance with some embodiments of the present disclosure, a device comprises a first semiconductor region; a first gate stack over the first semiconductor region; a dielectric layer aside of the first gate stack and the first semiconductor region; an amorphous semiconductor layer over and contacting the dielectric layer to form a first interface; and a crystalline semiconductor layer over the amorphous semiconductor layer, wherein a first sidewall of the first semiconductor region contacts a second sidewall of the crystalline semiconductor layer to form a second interface.

In an embodiment, the device further comprises a second semiconductor region, wherein the crystalline semiconductor layer contacts the second semiconductor region to form a third interface; and a second gate stack over the second semiconductor region, wherein the first interface continuously extends from a first point vertically aligned to the first interface to a second point vertically aligned to the second interface. In an embodiment, no void is formed between the amorphous semiconductor layer and the dielectric layer. In an embodiment, the amorphous semiconductor layer covers, and is in physical contact with an entire top surface of, the dielectric layer.

In an embodiment, the first semiconductor region comprises a first semiconductor nanostructure, and the device further comprises a second semiconductor nanostructure overlapped by the first semiconductor nanostructure, and wherein the first gate stack comprises a lower portion between the first semiconductor nanostructure and the second semiconductor nanostructure. In an embodiment, the device further comprises an inner spacer on a side of and contacting the lower portion of the first gate stack, wherein an entirety of the dielectric layer is lower than a bottom end of the inner spacer. In an embodiment, a topmost end of the amorphous semiconductor layer is lower than a top surface of the inner spacer.

In accordance with some embodiments of the present disclosure, a device comprises a plurality of nanostructures, with upper nanostructures in the plurality of nanostructures overlapping lower nanostructures in the plurality of nanostructures; a gate stack comprising a plurality of portions, each between a lower one and a respective upper one of the plurality of nanostructures; a plurality of pairs of inner spacers, with each pair being on opposing sides of a respective portion of the plurality of portions of the gate stack; a source/drain region comprising an amorphous semiconductor layer; and a crystalline semiconductor layer over and contacting the amorphous semiconductor layer; and a dielectric layer underlying and contacting the amorphous semiconductor layer. In an embodiment, no void is formed between the dielectric layer and the amorphous semiconductor layer. In an embodiment, the amorphous semiconductor layer contacts an entire top surface of the dielectric layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
etching a semiconductor region aside of a gate stack to form a recess;
forming a dielectric layer at a bottom of the recess;
selectively forming a first semiconductor layer at the bottom of the recess, wherein a bottom surface of the first semiconductor layer forms an interface with a top surface of the dielectric layer, with the interface extending to opposing sides of the recess, and wherein the selectively forming the first semiconductor layer comprises a first deposition process performed under first process conditions; and
epitaxially growing a second semiconductor layer on the first semiconductor layer, wherein the epitaxially growing the second semiconductor layer is formed using a second deposition process under second process conditions, and wherein the second process conditions are different from the first process conditions,
wherein the selectively forming the first semiconductor layer comprises a first deposition-and-etch cycle comprising:
the first deposition process to deposit a sub layer of the first semiconductor layer, wherein the sub layer comprises:
a top portion overlapping the gate stack;
a sidewall portion on a sidewall of the semiconductor region, with the sidewall being in the recess; and
a bottom portion at the bottom of the recess; and
an etch-back process to remove the top portion and the sidewall portion, with a part of the bottom portion remaining, and
wherein first deposition process is a directional deposition process that is performed with a bias power applied.
